(19) United States
(12) Patent Application Publication
(10) Pub. No.: US 2026/0251681 A1
(43) Pub. Date: Aug. 27, 2026

(54) METHOD FOR MANUFACTURING MICRO-ELECTROMECHANICAL PROBE

(71) Applicant: Syu Guang Technology co., ltd., Zhubei City (TW)

(72) Inventor: KUN YU WU, Zhubei City (TW)

(73) Assignee: Syu Guang Technology co., ltd., Zhubei City (TW)

(21) Appl. No.: 19/060,994

(22) Filed: Feb. 24, 2025

(51) Int. Cl. G01R 3/00; B23K 26/362; B81C 1/00; G03F 7/00

(52) U.S. Cl. CPC G01R 3/00; B23K 26/362; B81C 1/00111; G03F 7/0035

(57) ABSTRACT

A method for manufacturing micro-electromechanical probe includes: Coating an adhesive layer on a substrate; Coating a seed layer on the adhesive layer; Coating a photoresist layer with a thickness of 5 to 200 microns on the seed layer; Using a photolithography method through a photomask to form a mold cavity having a plurality of probe arrangement patterns in the photoresist layer; using an electroplating method to deposit a conductive material with the seed crystal material to form a plurality of metal layers in the shape of probes; applying laser etching to remove the photoresist around the metal layer; Fixing the probe; processed by laser to form an oxide layer; forming a thin film insulating oxide layer on the probes.

### BACKGROUND OF THE INVENTION

### 1. Field of the Invention

A method for manufacturing micro-electromechanical probe, especially to one that uses micro-electromechanical process and laser etching.

### 2. Description of the Related Art

In general semiconductor manufacturing processes, after wafer processing is completed but before cutting and packaging, the electrical characteristics of the IC at the wafer stage must be tested with a probe card, feeding back the results to the front-end process to ensure the yield of wafer processing; At the same time, defective products can be eliminated first to avoid waste in the later packaging process, thereby achieving the effect of reducing costs and increasing production capacity. During the test, the probes on the probe card contact the pads or bumps on the IC chip to form a test circuit; the signal sent by the tester is transmitted to the chip through the probe, and the chip feedback data is sent back to the tester for analysis and judgment, so as to detect whether the function of each chip on the wafer is normal.

In recent years, with the high integration of semiconductor chips, the pads on the chips have become thinner and the pitch has become smaller. Since the probes on the probe cards in the test equipment must be reduced accordingly, probes made using micro-electromechanical processes have emerged. Micro-electromechanical Systems (MEMS) is an industrial technology that combines microelectronics with mechanical engineering, its operating range is within the micrometer scale, and the size of a general MEMS device is between 1 micron and 1 millimeter.

Taiwan patent No. 202009496 disclosed a method for manufacturing a MEMS probe for semiconductor inspection using laser. In the method for manufacturing a probe using a MEMS process, the method includes: a first step, depositing a sacrificial layer on a substrate; a second step, coating the above-mentioned sacrificial layer Photoresist; the third step is to form a photoresist pattern in the shape of a square array of probes extending from one side of the support part; the fourth step is to form a photoresist pattern along the above photoresist pattern A metal layer is formed; the fifth step is to remove the photoresist; the sixth step is to perform etching to remove the sacrificial layer located below the probe while not removing the sacrificial layer located below the support portion The seventh step, the use of an adhesive member to fix the probe; the eighth step, the use of a laser to cut the probe from the support part; and the ninth step, the separation of the probe from the adhesive member. As showing in FIG. 1A, deposit a sacrificial layer 920 on the substrate 910, then coat the photoresist 930; As showing in FIG. 1B~1C, deposit a plurality of probes are elongated in the shape of a square array of probes to form a photoresist pattern 940, then form a metal layer 950 along the photoresist pattern 40; remove the photoresist; etching is performed to remove the sacrificial layer 920 while not removing the support portion 970, the metal layer 950 is supported by it; using adhesive member 980 to fix the probe 52. As showing in FIG. 2A~2B, the laser is used to cut the probe 990 from the support 970, and the probe 990 is separated from the adhesive member 980. The above steps must be divided into two stages, and the sacrificial layer 920 and the support portion 970 are removed by etching in turn. Since the sacrificial layer 920 and the support portion 970 are both conductive materials, the etching process requires a long time and a large amount of electricity. Moreover, during the etching process of the support portion 970, debris often remains, causing the probe surface to lose its smoothness, thereby affecting the accuracy of subsequent wafer detection. Therefore, how to improve the quality and production efficiency of probe production has become the goal of this patent.

### SUMMARY OF THE INVENTION

A primary objective of the present invention is to provide a method for manufacturing micro-electromechanical probe, which has the effect of improving the quality and production efficiency of probe production, thereby ensuring the reliability and effectiveness of the wafer inspection process.

Another objective of the present invention is to form a thin film insulating oxide layer during the manufacturing process of the probe, thereby increasing the effectiveness of the probe's insulation protection.

Another objective of the present invention is to include a probe appearance defect detection and an impedance detection in the manufacturing process, thereby increasing the reliability and quality of the probe.

In order to achieve the above objectives, the steps of the present invention includes: a). Coating an adhesive material on a surface of a substrate to form an adhesive layer; b). Coating a seed crystal material on a surface of the adhesive layer to form a seed layer; c). Coating a photoresist material on a surface of the seed layer to form a photoresist layer with a thickness of 5 to 200 microns; d). Using a photolithography method through a photomask to form a mold cavity having a plurality of probe arrangement patterns in the photoresist layer; e). Using an electroplating method to deposit a conductive material with the seed crystal material in the mold cavity of the previous step to form a plurality of metal layers in the shape of probes; f). Applying laser etching to irradiate the front side of the substrate to remove the photoresist around the metal layer; g). Using an adhesive positioning unit to adhere to the surface of the metal layer for making the probe be fixed on the positioning unit; h). First, the adhesive layer, the seed layer and the metal layer are partially processed by laser to form an oxide layer; i). forming a thin film insulating oxide layer on the partial surface of the plurality of probes; j). Perform defect detection and impedance test on the probes; k). Vaporizing the adhesive layer by applying laser etching to irradiate the adhesive layer; l). Separating the probes from the positioning unit.

Also, the laser etching described in step f). and step k). is performed by applying a laser light source to provide a laser beam; A laser scanning module is arranged on the transmission path of the laser beam, which has an X-Y optical scanning lens and an optical reflective lens, through the reflection of the optical reflective lens and the focusing of the X-Y optical scanning lens, the focusing of a laser spot and a corresponding angle shift are achieved, so that the laser beam is deflected and focused on the desired irradiation point, then the laser beam is projected onto a workpiece to generate a response beam, and the response beam will be further collected by the X-Y optical scanning lens and reflected by the optical reflective lens for analysis of the laser beam irradiation status; A visual module, arranged on the transmission path of the laser beam and the response beam, so that the visual module can be used to inspect the relative position state of the laser beam projected on the desired irradiation position and the relative position state of the response beam; A translational movement platform, arranged on the opposite side of the laser light source, and has a working platform and a displacement mechanism capable of at least two axes, X and Y; Whereby, the substrate and the attachments thereon described in step f). and step k). are placed on the working platform, and then uses the visual module to inspect and drive the X-Y optical scanning lens and the displacement mechanism to move in coordination, so that the laser beam is projected correspondingly on the desired irradiation point, thereby completing the laser etching operation.

Also, the material of the substrate in step a). includes any one of ceramic, glass, metal, plastic and semiconductor wafer.

Also, the adhesive material in step a). includes metal or a combination of colloid and metal; The aforementioned metal includes any one of copper, chromium, tungsten, nickel, nickel-chromium alloy, nickel-copper alloy, nickel-cobalt alloy, nickel-phosphorus alloy, lead and gold; and the aforementioned colloid includes any one of acrylic glue, epoxy resin, polyimide and PET.

Also, the positioning unit described in step g). includes a film.

Also, the wavelength of the laser beam is 355 nm~1070 nm.

The present invention sequentially coats an adhesive layer, a seed layer, and a photoresist layer on the surface of a substrate; forms a mold cavity having a plurality of probe arrangement patterns in the photoresist layer by photolithography; then deposits a metal layer by electroplating in the mold cavity; and finally uses laser etching to first remove the photoresist and then vaporize the adhesive layer; since the laser etching process does not consume too much time and power, and there is no accumulation of any debris on the probe surface, so the micro-electromechanical probe produced by the present invention has high quality and cost-effectiveness.

### BRIEF DESCRIPTION OF THE DRAWINGS

FIG. 1A is a schematic diagram illustrating the micro-electromechanical probe pre-process of the prior art;

FIG. 1B is a schematic diagram illustrating the micro-electromechanical probe pre-process of the prior art;

FIG. 1C is a schematic diagram illustrating the micro-electromechanical probe pre-process of the prior art;

FIG. 2A is a schematic diagram illustrating the micro-electromechanical probe post-process of the prior art;

FIG. 2B is a schematic diagram illustrating the micro-electromechanical probe post-process of the prior art;

FIG. 3 is a block diagram illustrating the manufacturing step of the present invention;

FIG. 4 is a schematic diagram illustrating the step g). of the present invention;

FIG. 5A is a schematic diagram illustrating the status after complete step g). of the present invention;

FIG. 5B is a schematic diagram illustrating the probe arrangement of an embodiment of the present invention;

FIG. 6A is a schematic diagram illustrating the oxide layer work of the step h). and step i). of the present invention;

FIG. 6B is a sectional view along line 6B-6B in FIG. 6A;

FIG. 6C is a schematic diagram illustrating the impedance test in step j). of the present invention;

FIG. 7 is a schematic diagram illustrating the step k). of the present invention;

FIG. 8 is a schematic diagram illustrating the device of laser etching of the present invention;

FIG. 9 is a schematic diagram illustrating the laser etching work of the present invention;

FIG. 10 is a schematic diagram illustrating the status after complete step k). of the present invention;

FIG. 11 is a schematic diagram illustrating the probe separate from the positioning unit in step l). of the present invention;

FIG. 12 is a schematic diagram illustrating the probe of the present invention assembled on the guide plate.

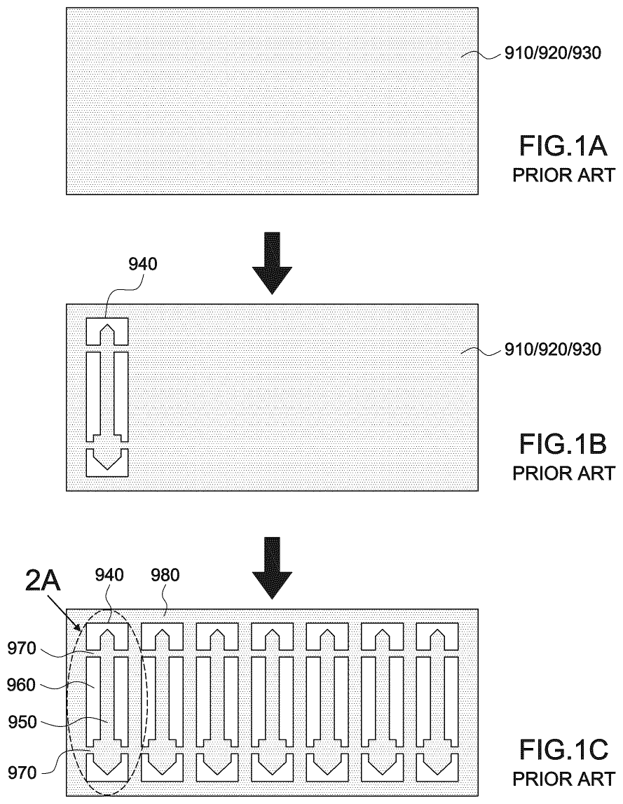

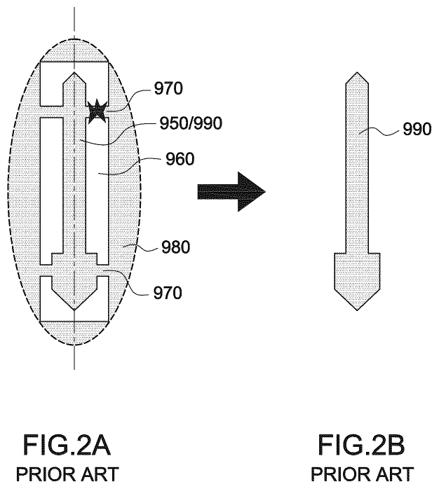

### DETAILED DESCRIPTION OF THE PREFERRED EMBODIMENT

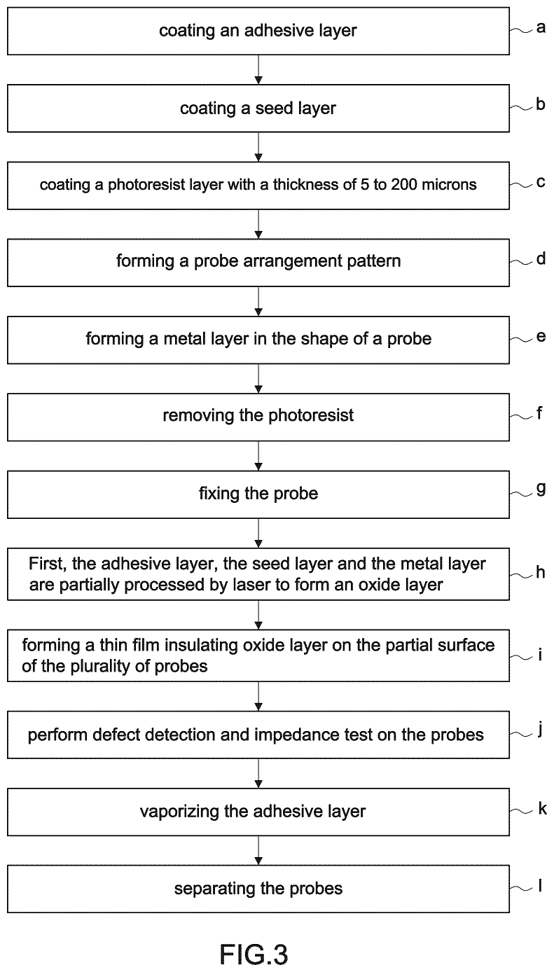

Referring to FIG. 3, the present invention, a method for manufacturing micro-electromechanical probe includes:
a). coating an adhesive layer 12: Coating an adhesive material on a surface of a substrate 11 to form an adhesive layer 12;
b). coating a seed layer: Coating a seed crystal material on a surface of the adhesive layer 12 to form a seed layer;
c). coating a photoresist layer: Coating a photoresist material on a surface of the seed layer to form a photoresist layer with a thickness of 5 to 200 microns;
d). forming a probe arrangement pattern: using a photolithography method through a photomask to form a mold cavity having a plurality of probe arrangement patterns in the photoresist layer;
e). forming a metal layer in the shape of a probe: using an electroplating method to deposit a conductive material with the seed crystal material in the mold cavity of the previous step to form a plurality of metal layers in the shape of probes;
f). Removing the photoresist: applying laser etching to irradiate the front side of the substrate to remove the photoresist around the metal layer;
g). Fixing the probe: using an adhesive positioning unit to adhere to the surface of the metal layer for making the probe be fixed on the positioning unit;
h). First, the adhesive layer, the seed layer and the metal layer are partially processed by laser to form an oxide layer;
i). forming a thin film insulating oxide layer on the partial surface of the plurality of probes;
j). Perform defect detection and impedance test on the probes;
k). Vaporizing the adhesive layer: applying laser etching to irradiate the adhesive layer at the back side of the substrate to vaporize and remove the adhesive material; and
l). Separating the probes: separating the probes from the positioning unit one by one.

The substrate in step a). is only used in the process of manufacturing the probe, and the material coated thereon can be removed or evaporated in the subsequent process without damaging the substrate; therefore, the substrate is a reusable material; Step b). refers to a seed layer, wherein the “seed” refers to the formation of crystal nuclei by adding insoluble additives in the crystallization method to accelerate or promote the growth of enantiomer crystals with respect to its crystal form or its spatial configuration; in other words, the seed is a small single crystal that can be placed in a saturated or supersaturated solution to grow a larger crystal. Step c). refers to a photoresist layer, the photoresist is a light-sensitive mixed liquid composed of three main components: photosensitive resin, sensitizer and solvent.

Also, the material of the substrate 11 in step a). includes any one of ceramic, glass, metal, plastic and semiconductor wafer. The adhesive material in step a). includes metal or a combination of colloid and metal; The aforementioned metal includes any one of copper, chromium, tungsten, nickel, nickel-chromium alloy, nickel-copper alloy, nickel-cobalt alloy, nickel-phosphorus alloy, lead and gold; and the aforementioned colloid includes any one of acrylic glue, epoxy resin, polyimide and PET.

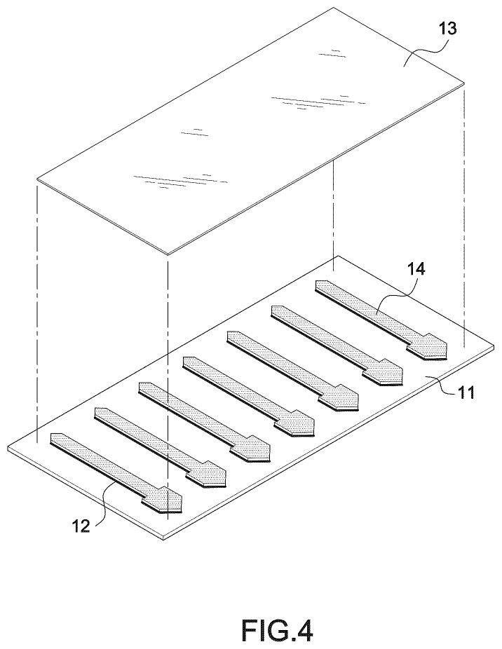

Referring to FIG. 4~5A, illustrating the step g). of the present invention; In the process of steps a).~f)., the probe 14 of the metal layer is already formed on the surface of the substrate 11, there is an adhesive layer 12 between the probe 14 and the substrate 11, and the photoresist originally present around the metal layer has been removed; Therefore, once the substrate 11 is to be separated in the subsequent process, the probe 14 will inevitably fall off in a disorderly manner and cause damage; Therefore, in step g)., an adhesive positioning unit 13 is adhered to the surface of the metal layer to fix the probe 14 on the positioning unit 13; in the present invention, the positioning unit 13 can be a film, but is not limited thereto.

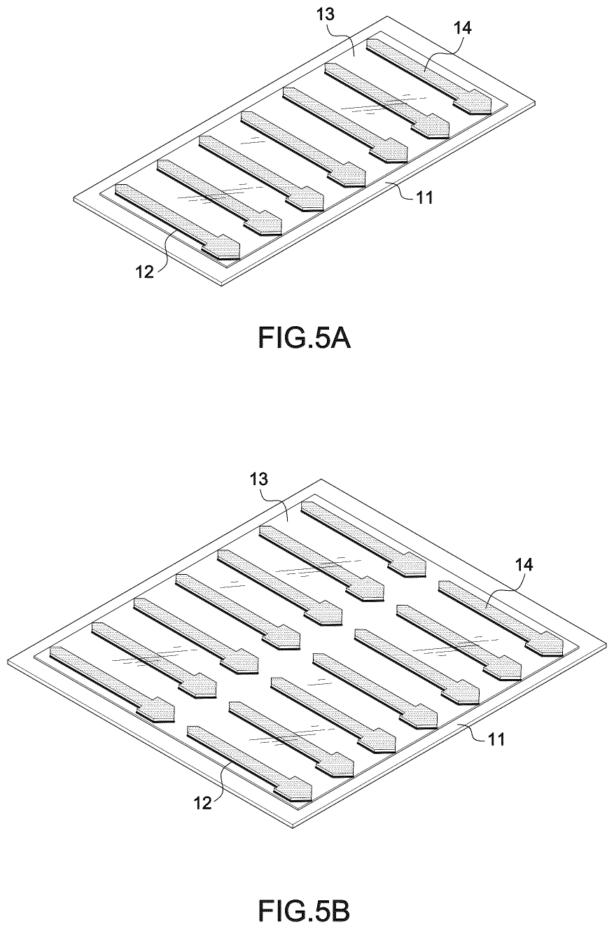

Referring to FIG. 5B, a schematic diagram illustrating the probe arrangement of an embodiment of the present invention; In this embodiment, a double arrangement is presented. However, whether it is a single arrangement, a double arrangement, or even a multiple arrangement, the above-mentioned process is exactly the same.

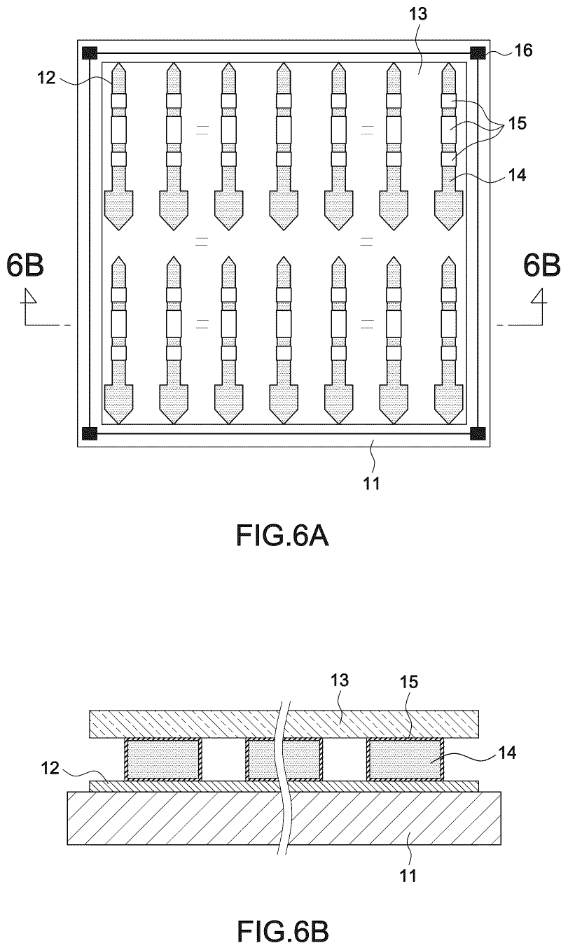

Referring to FIG. 6A~6B, illustrating the oxide layer work of the step h). and step i). of the present invention; In this embodiment, the process is divided into two steps. First, the adhesive layer, seed layer and metal layer are processed locally by laser to form an oxide layer. Then, a thin film insulating oxide layer 15 is formed on the local surface of the probe 14 by any method such as ALD, PVD, CVD, Dipping, etc. The purpose is to prevent the probe from deforming, shifting, decreasing the spacing, or causing leakage when pressed down in the future. Therefore, the present invention adds 2 to 3 thin film insulating oxide layers 15 for insulation protection.

Step j). Perform defect detection and impedance test on the probes 14; in this embodiment, using an automated optical inspection device, AOI, to perform defect detection on the probe. The working principle of AOI is to use a CCD camera to capture the image of the object being tested, compare it with the actual reference image through image recognition, and then identify whether the tested component is good or not through complex calculations and analysis. However, the features of AOI belong to prior art and is not the patent subject of the present invention, so will not describe in detail.

Referring to FIG. 6C, step j). perform impedance test on the probes 14; In this embodiment, a four-point probe resistance meter can be used to measure the impedance. The features of four-point probe resistance meter belong to prior art and is not the patent subject of the present invention, so will not describe in detail. For example: as shown in FIG. 6C, the test pads 16 at the four corners of the substrate 11 are connected to form a loop 1 for single-point resistance (insulation) testing; the probe 14 and the thin film oxide layer 15 form a loop 2, the thin film oxide layer 15 requires 1-3 areas for insulation testing, the testing method is the same as loop 1 and is mainly used for comparison and confirmation with loop 1. Therefore, the purpose of step j). is to increase the reliability and quality of the probe 14 after manufacture.

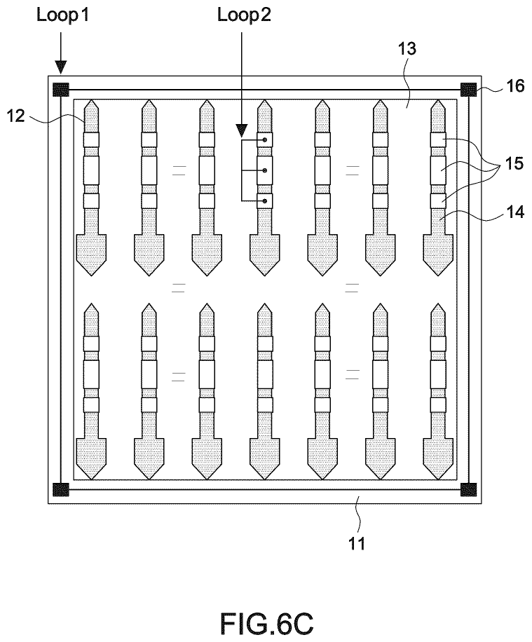

Referring to FIG. 7, illustrating vaporizing the adhesive layer of the step k). of the present invention; vaporizing the adhesive layer is the main feature of the present invention, applying laser etching to irradiate the adhesive layer 12 at the back side of the substrate 11 to vaporize and remove the adhesive material; The laser etching device of the present invention is a large-area laser beam scanning device 100, the scanning head of the device projects a laser beam with a wavelength of 355 nm to 1070 nm to irradiate the adhesive layer 12, and the substrate 11 with the plurality of probes 14 attached thereto is placed on the stage of the device, with the back of the substrate 11 facing upwards. By the relative movement of the scanning head and the stage or by one fixed and the other one moving, the adhesive layer 12 is irradiated by the laser beam area by area and point by point and evaporates.

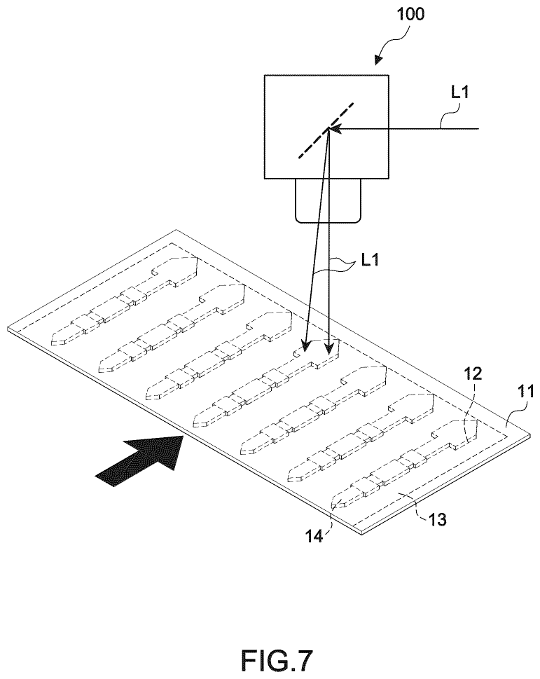

The laser etching device used in step f). and step k). of the present invention is a large-area laser beam scanning device 100, as FIG. 8 showing, a laser light source 20 which is a laser machine 21 to provide a laser beam L1 projected onto a workpiece M; A translational movement platform 30, arranged on the opposite side of the laser light source 20, and has a working platform and a displacement mechanism capable of at least two axes, X and Y; the displacement mechanism also capable displace on Z axis, so that the working platform can be raised or lowered in height in accordance with the projection focal length of the laser beam L1; a laser scanning module 40 is arranged above the translational movement platform 30 and arranged on the transmission path of the laser beam L1, which has an X-Y optical scanning lens 41 and an optical reflective lens 42, through the reflection of the optical reflective lens 42 turning its horizontal projection direction downward, and through the focusing of the X-Y optical scanning lens 41,, thereby achieving the focusing of the laser spot and generating the corresponding angle shift, so that the laser beam L1 is deflected and focused on the desired irradiation point of the workpiece M, then workpiece M generates a photoluminescent response beam R1, and the response beam R1 will be further collected by the X-Y optical scanning lens 41 and reflected by the optical reflective lens 42, so that the response beam R1 is transmitted in the horizontal direction for analysis of the laser beam irradiation status. A visual module 50, having a beamsplitter set 51 arranged on the transmission path of the laser beam L1 and the response beam R1, so that the visual module 50 can be used to inspect the relative position state of the laser beam L1 projected on the desired irradiation position and the relative position state of the response beam R1; and drive the X-Y optical scanning lens 41 and the displacement mechanism 30 to move in coordination, so that the laser beam L1 is projected correspondingly on the desired irradiation point, thereby completing the laser etching operation.

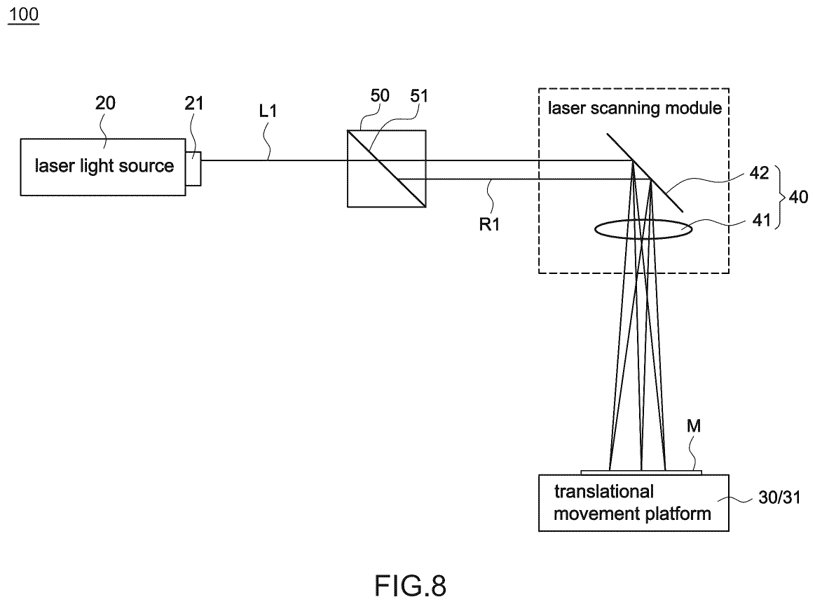

Referring to FIG. 9, which shows the status of laser etching of the present invention; Wherein the workpiece M is placed on the working platform 31, the laser machine 21 emits a laser beam L1 which is refracted by the optical reflective lens 42, so that the horizontal laser beam L1 is turned to the working platform 31 below, and the setting state of the related components is inspected and adjusted by the visual module 50, and then drives the working platform 31 of the translational movement platform 30 to move the desired irradiation area; After the irradiation area is positioned, the optical reflective lens 42 of the laser scanning module 40 is used to perform angle deflection so that the laser beam L1 is projected one by one on the desired irradiation points. In this operation, the irradiation area can be divided into 9 irradiation points. Each square in the figure represents the irradiation field of view area S of the X-Y optical scanning lens 41 after the translational movement platform 30 is shifted. Through the individual deflection of the optical reflective lens 42, the laser beam L1 is projected one by one on the desired irradiation point P from the first point in the upper left corner to the ninth point in the lower right corner, the photoluminescent response beam R1 of each point is illuminated,, the light collected by the X-Y optical scanning lens 41 and reflected by the optical reflective lens 42 are then monitored by the visual module 50; After completing the irradiation of each irradiation point P in the irradiation field of view area S, the translational movement platform 30 will once again move to a new irradiation field of view area S and repeatedly irradiate each irradiation point P one by one; this is repeated continuously and one by one in each irradiation field of view area S to complete the laser etching operation.

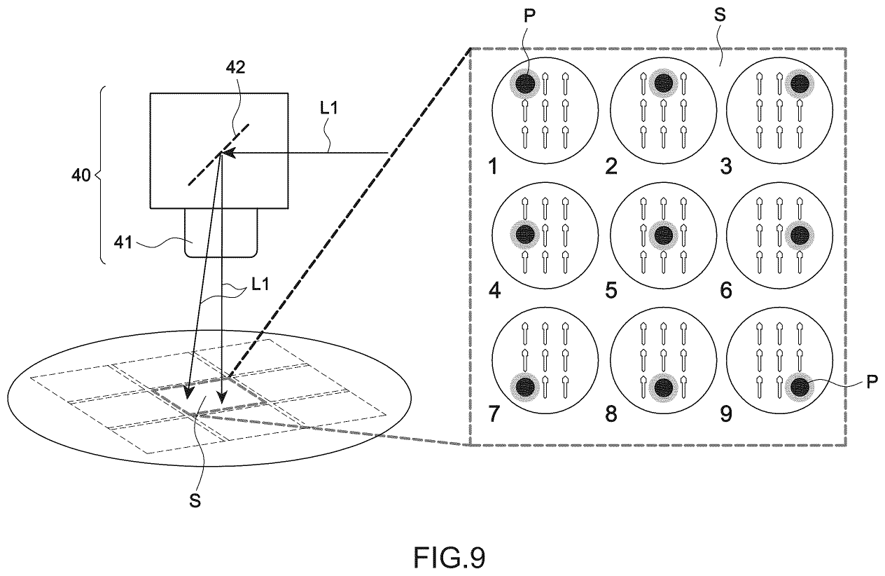

FIG. 10 is a schematic diagram illustrating the status after complete step k). of the present invention; Since the probe 14 is fixed on the positioning unit 13, the adhesive layer 12 between the probe 14 and the substrate 11 is vaporized and disappears due to being irradiated by the laser beam area by area, so the probe 14 and the substrate 11 are separated, but still fixed on the positioning unit 13.

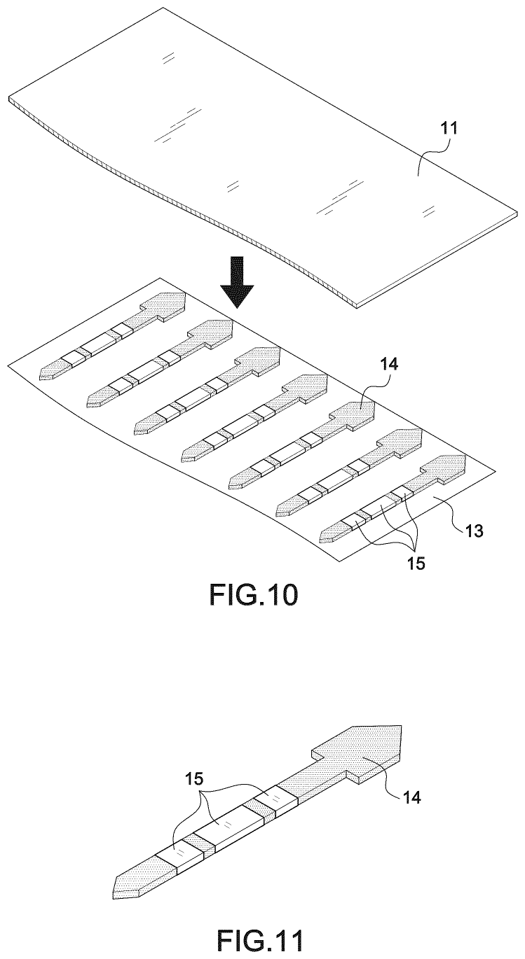

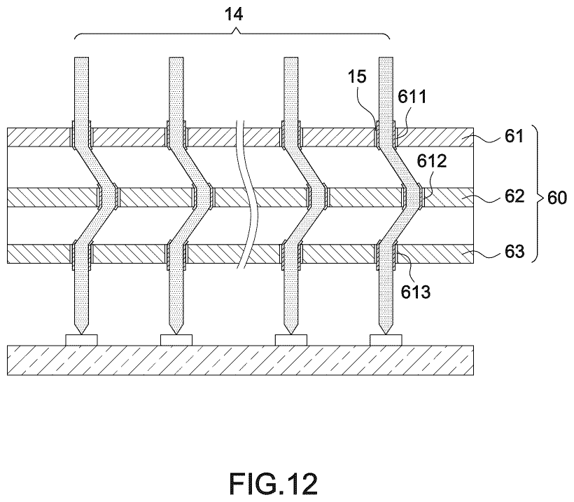

FIG. 11 is a schematic diagram illustrating the probe 14 separate from the positioning unit 13 in step l). of the present invention, at this time, 2 to 3 thin film insulating oxide layers 15 are formed on the probe 14. FIG. 12 is a schematic diagram illustrating the probe 14 of the present invention assembled on a guide plate device 60; In this embodiment, the guide plate device 60 includes an upper guide plate 61, a middle guide plate 62, and a lower guide plate 63, which are three plates in total; but the present invention is not limited to this application. In other embodiments, two guide plates are used. The thin film insulating oxide layer 15 on the probe 14 of the present invention can prevent deformation, displacement, reduced spacing, leakage, etc. when the probe 14 passes through holes 611, 612, 613 of the guide plate or when pressed down, thereby having the effect of insulation protection.

The present invention sequentially coats an adhesive layer 12, a seed layer, and a photoresist layer on the surface of a substrate 11; forms a mold cavity having a plurality of probe arrangement patterns in the photoresist layer by photolithography; then deposits a metal layer by electroplating in the mold cavity; and finally uses laser etching to first remove the photoresist and then vaporize the adhesive layer; and 2 to 3 thin film insulating oxide layers 15 are formed on the manufactured probe 14 at the same time. Since the laser etching process does not consume too much time and power, and there is no accumulation of any debris on the probe 14 surface, so the micro-electromechanical probe produced by the present invention has high quality and cost-effectiveness.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A method for manufacturing micro-electromechanical probe, includes:
a). coating an adhesive layer: Coating an adhesive material on a surface of a substrate to form an adhesive layer;
b). coating a seed layer: Coating a seed crystal material on a surface of the adhesive layer to form a seed layer;
c). coating a photoresist layer: Coating a photoresist material on a surface of the seed layer to form a photoresist layer with a thickness of 5 to 200 microns;
d). forming a probe arrangement pattern: using a photolithography method through a photomask to form a mold cavity having a plurality of probe arrangement patterns in the photoresist layer;
e). forming a metal layer in the shape of a probe: using an electroplating method to deposit a conductive material with the seed crystal material in the mold cavity of the previous step to form a plurality of metal layers in the shape of probes;
f). Removing the photoresist: applying laser etching to irradiate the front side of the substrate to remove the photoresist around the metal layer;
g). Fixing the probe: using an adhesive positioning unit to adhere to the surface of the metal layer for making the probe be fixed on the positioning unit;
h). First, the adhesive layer, the seed layer and the metal layer are partially processed by laser to form an oxide layer;
i). forming a thin film insulating oxide layer on the partial surface of the plurality of probes;
j). Perform defect detection and impedance test on the probes;
k). Vaporizing the adhesive layer: applying laser etching to irradiate the adhesive layer at the back side of the substrate to vaporize and remove the adhesive material;
l). Separating the probes: separating the probes from the positioning unit one by one; and
The laser etching described in step f). and step k). is performed by applying a laser light source to provide a laser beam;
A laser scanning module is arranged on the transmission path of the laser beam, which has an X-Y optical scanning lens and an optical reflective lens, through the reflection of the optical reflective lens and the focusing of the X-Y optical scanning lens, the focusing of a laser spot and a corresponding angle shift are achieved, so that the laser beam is deflected and focused on the desired irradiation point, then the laser beam is projected onto a workpiece to generate a response beam, and the response beam will be further collected by the X-Y optical scanning lens and reflected by the optical reflective lens for analysis of the laser beam irradiation status;
A visual module, arranged on the transmission path of the laser beam and the response beam, so that the visual module can be used to inspect the relative position state of the laser beam projected on the desired irradiation position and the relative position state of the response beam;
A translational movement platform, arranged on the opposite side of the laser light source, and has a working platform and a displacement mechanism capable of at least two axes, X and Y;
Whereby, the substrate and the attachments thereon described in step f). and step k). are placed on the working platform, and then uses the visual module to inspect and drive the X-Y optical scanning lens and the displacement mechanism to move in coordination, so that the laser beam is projected correspondingly on the desired irradiation point, thereby completing the laser etching operation.

2. The method for manufacturing micro-electromechanical probe as claimed in claim 1, wherein the material of the substrate in step a). includes any one of ceramic, glass, metal, plastic and semiconductor wafer.

3. The method for manufacturing micro-electromechanical probe as claimed in claim 1, wherein the adhesive material in step a). includes metal or a combination of colloid and metal; The aforementioned metal includes any one of copper, chromium, tungsten, nickel, nickel-chromium alloy, nickel-copper alloy, nickel-cobalt alloy, nickel-phosphorus alloy, lead and gold; and the aforementioned colloid includes any one of acrylic glue, epoxy resin, polyimide and PET.

4. The method for manufacturing micro-electromechanical probe as claimed in claim 1, wherein the positioning unit described in step g). includes a film.

5. The method for manufacturing micro-electromechanical probe as claimed in claim 1, wherein the wavelength of the laser beam is 355 nm~1070 nm.
